(19) United States
(12) Patent Application Publication
(10) Pub. No.: US 2010/0159165 A1
(43) Pub. Date: Jun. 24, 2010

(54) TRANSFER SUBSTRATE AND METHOD OF MANUFACTURING A DISPLAY APPARATUS

(75) Inventors: Kenji Ueda, Kanagawa (JP); Tomoyuki Higo, Tokyo (JP)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: SONY CORPORATION, Tokyo (JP)

(21) Appl. No.: 12/635,156

(22) Filed: Dec. 10, 2009

(30) Foreign Application Priority Data
Dec. 24, 2008 (JP) 2008-326860

(51) Int. Cl. B41M 5/40; B41M 5/382; H01J 9/00

(52) U.S. Cl. 428/32.8; 428/32.6; 445/24

(57) ABSTRACT

A transfer substrate includes a support substrate for thermal transfer and a transfer layer. The transfer layer is provided on the support substrate, and includes a host material and a luminescent dopant material each having a sublimation temperature. A difference of the sublimation temperatures is set within a predetermined range.

### BACKGROUND OF THE INVENTION

1. Field of the Invention

The present invention relates to a transfer substrate and a method of manufacturing a display apparatus, and more particularly, to a transfer substrate for manufacturing a display apparatus that uses an organic light emitting diode and a method of manufacturing a display apparatus with use of the transfer substrate.

2. Description of the Related Art

Along with enlargement of a substrate, application of a thermal transfer method for adding different colors to light emitting layers has been examined in manufacture of a display apparatus formed by arranging a plurality of OLEDs (Organic Light Emitting Diodes) on the substrate. As the thermal transfer method, there are well known a method of performing transfer by direct heating using a heater or the like, and a method of performing transfer by converting a laser beam into heat. In any of the heating methods, a transfer substrate obtained by forming, by vacuum deposition, or applying a transfer layer made of a luminescent material on a support substrate is used. In the thermal transfer method using this transfer substrate, by performing heating with a heater or laser irradiation from the transfer substrate side with the transfer substrate facing an apparatus substrate, the transfer layer is thermally transferred to the apparatus substrate side and thus a light emitting layer is formed.

In a case where a light emitting layer containing multiple components of a host material and a guest material is formed by applying the thermal transfer method as described above, there is used a transfer substrate including a thermal transfer layer made of a host material and a guest material whose type and blend ratio are optimized. However, an OLED in which the light emitting layer containing multiple components is formed by the thermal transfer method tends to be inferior in luminescent property, compared with an OLED in which the light emitting layer containing multiple components is formed by vapor deposition.

In this regard, it is proposed that an oxygen concentration or water concentration is controlled to be low, as in a case where an atmosphere in a transfer process, a transport process prior to the transfer, a bonding apparatus, and the like is changed to an inert atmosphere (Japanese Patent Application Laid-open Nos. 2003-332062 and 2004-79317).

### SUMMARY OF THE INVENTION

However, in spite of the atmosphere control as described above, luminescent properties of OLEDs formed by vapor deposition and thermal transfer are different depending on a combination of used host material and dopant material or an emission color. In addition, even when the same transfer method is used, obtained OLEDs differ from each other in luminescent property depending on a heating method of the transfer layer. For that reason, there are cases, for example, where even in the light emitting layer that uses a host material and a dopant material whose luminescent properties are not the best when vapor deposition is applied, the luminescent properties may become the best when the thermal transfer is applied, and vice versa.

In view of the circumstances as described above, there is a need for a transfer substrate that is capable of obtaining an organic light emitting diode with stable luminescent properties even in a case where an light emitting layer is formed by thermal transfer, and a method of manufacturing a display apparatus.

According to an embodiment of the present invention, there is provided a transfer substrate including a support substrate for thermal transfer and a transfer layer that is provided on the support substrate. Particularly, the transfer layer includes a host material and a luminescent dopant material, and a difference of sublimation temperatures of those materials is set within a predetermined range.

Further, according to another embodiment of the present invention, there is provided a transfer method using the transfer substrate as described above. In this transfer method, the host material and the dopant material are uniformly sublimated by heating a transfer layer formed on the transfer substrate, and a light emitting layer is formed by thermally transferring the transfer layer including the host material and the dopant material to an apparatus substrate.

According to the embodiments of the present invention, the difference between the sublimation temperatures of the host material and the luminescent dopant material that constitute the transfer layer is set within the predetermined range. Therefore, the host material and the luminescent dopant material are sublimated nearly at the same time in the thermal transfer using that transfer substrate. Accordingly, the light emitting layer in which the host material and the dopant material are uniformly distributed in a depth direction is formed by the thermal transfer.

As a result, according to the embodiments of the present invention, an organic light emitting diode with stable luminescent properties can be obtained even in a case where a light emitting layer is formed by thermal transfer, and a display apparatus with excellent display properties can be obtained as shown in the embodiment described later.

These and other objects, features and advantages of the present invention will become more apparent in light of the following detailed description of best mode embodiments thereof, as illustrated in the accompanying drawings.

### BRIEF DESCRIPTION OF DRAWINGS

FIG. 1 is a cross-sectional view showing a structure of a transfer substrate according to an embodiment of the present invention;

FIG. 2 are cross-sectional process views (part 1) showing a method of manufacturing a display apparatus according to the embodiment;

FIG. 3 are cross-sectional process views (part 2) showing the method of manufacturing the display apparatus according to the embodiment;

FIG. 4 are cross-sectional process views (part 3) showing the method of manufacturing the display apparatus according to the embodiment;

FIG. 5 is a diagram showing an example of a circuit structure in a liquid crystal display apparatus according to the embodiment;

FIG. 6 is a perspective view showing a television to which the embodiment of the present invention is applied;

FIG. 7 are views showing a digital camera to which the embodiment of the present invention is applied, in which FIG. 7A is a perspective view seen from a front side and FIG. 7B is a perspective view seen from a backside;

FIG. 8 is a perspective view showing a laptop personal computer to which the embodiment of the present invention is applied;

FIG. 9 is a perspective view showing a video camera to which the embodiment of the present invention is applied;

FIG. 10 are views showing a mobile terminal apparatus, for example, a cellular phone, to which the embodiment of the present invention is applied, in which FIG. 10A is a front view in an open state, FIG. 10B is a side view in the open state, FIG. 10C is a front view in a closed state, FIG. 10D is a left-hand side view, FIG. 10E is a right-hand side view, FIG. 10F is a top view, and FIG. 10G is a bottom view;

FIG. 11 is a graph based on Table 1, showing a relationship between a difference in sublimation temperatures and a ratio of luminescent properties in a case where a green light emitting layer is thermally transferred by laser irradiation;

FIG. 12 is a graph based on Table 2, showing the relationship between the difference in sublimation temperatures and the ratio of luminescent properties in a case where the green light emitting layer is thermally transferred by heating with a heater;

FIG. 13 is a graph based on Table 3, showing the relationship between the difference in sublimation temperatures and the ratio of luminescent properties in a case where a red light emitting layer is thermally transferred by laser irradiation; and

FIG. 14 is a graph based on Table 4, showing the relationship between the difference in sublimation temperatures and the ratio of luminescent properties in a case where the red light emitting layer is thermally transferred by heating with a heater.

### DESCRIPTION OF PREFERRED EMBODIMENTS

Hereinafter, an embodiment of the present invention will be described in the following order.

1. Structure of transfer substrate according to embodiment

2. Method of manufacturing display apparatus according to embodiment

3. Circuit structure of display apparatus

4. Application examples of electronic apparatus using display apparatus

(1. Structure of Transfer Substrate)

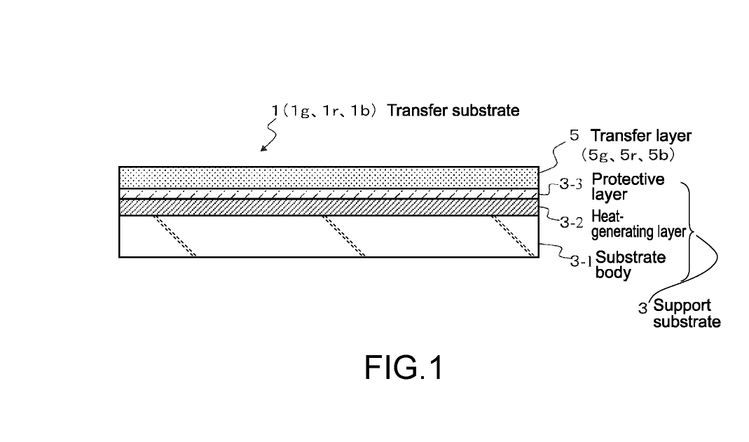

FIG. 1 is a cross-sectional view schematically showing a transfer substrate according to the embodiment of the present invention. A transfer substrate 1 shown in FIG. 1 is used for forming an organic light emitting layer in an OLED (Organic Light Emitting Diode) by a thermal transfer method when a display apparatus using the OLED is manufactured. Such a transfer substrate 1 refers to a transfer substrate 1g for forming an organic light emitting layer that emits green light, a transfer substrate 1r for forming an organic light emitting layer that emits red light, and a transfer substrate 1b for forming an organic light emitting layer that emits blue light.

Each of the transfer substrates 1g, 1r, and 1b is provided with a transfer layer 5 on a support substrate 3 for thermal transfer. The support substrate 3 is formed by laminating, for example, a heat-generating layer 3-2 and a protective layer 3-3 in the stated order on a substrate body 3-1 and on the protection layer 3-3, the transfer layer 5 is provided. Hereinafter, details of the respective layers will be described one by one from the support substrate 3 side.

The substrate body 3-1 that constitutes the support substrate 3 for thermal transfer may be formed of any material as long as the material is sufficiently smooth and has light transmissive properties and resistance to a temperature for heating, and is made of a glass substrate, a quartz substrate, a translucent ceramics substrate, or the like. In addition, a resin substrate may be used as long as there is no problem in size controllability with respect to a heating temperature. Here, a glass substrate having a thickness of 0.1 to 3.0 mm is used as the substrate body 3-1, for example.

It is assumed that the heat-generating layer 3-2 is made of a material that is appropriate for a heat source of a thermal transfer method.

For example, in a case where a laser beam is used as the heat source of the thermal transfer method, the heat-generating layer 3-2 is desirably provided with a structure in which a photothermal conversion layer is laminated on an anti-reflective layer, that is, a structure in which the anti-reflective layer and the photothermal conversion layer are disposed in the stated order from the substrate body 3-1 side. Of those layers, the anti-reflective layer is a layer for effectively containing a laser beam hν that is applied from the substrate body 3-1 side in the photothermal conversion layer, and is made of, for example, amorphous silicon having a thickness of 40 nm. The anti-reflective layer as described above is deposited on the substrate body 3-1 by CVD, for example. For the photothermal conversion layer, a material having a low reflectance with respect to a wavelength range of an energy line (laser beam, for example) that is used as a heat source in a thermal transfer process using the transfer substrate is desirably used. For example, in a case where a laser beam having a wavelength of about 800 nm from a solid-state laser light source is used, chromium (cr), molybdenum (Mo), or the like is desirably used as a material having a low reflectance and a high melting point. Here, a photothermal conversion layer made of molybdenum having a thickness of 40 nm is used. Such a photothermal conversion layer is deposited on the anti-reflective layer by sputtering, for example.

Further, in a case where a direct heat source such as a heater is used as the heat source of the thermal transfer method, the heat-generating layer 3-2 is formed of a material excellent in thermal conductivity. It should be noted that such a heat-generating layer 3-2 may be provided with a structure similar to that of the photothermal conversion layer described above, for example.

The protective layer 3-3 is a layer for preventing a material constituting the heat-generating layer 3-2 from being diffused. For example, examples of the material include silicon nitride (SiNₓ) and silicon oxide (SiO₂). The protective layer 3-3 is formed by, for example, CVD (Chemical Vapor Deposition).

The transfer layer 5 is a layer that becomes a transfer target in the thermal transfer method performed by using the transfer substrate 1 (1g, 1r, 1b) and is transferred as an organic light emitting layer of an OLED. The transfer layer 5 refers to a green transfer layer 5g for forming an organic light emitting layer that emits green light, a red transfer layer 5r for forming an organic light emitting layer that emits red light, and a blue transfer layer 5b for forming an organic light emitting layer that emits blue light. Those transfer layers 5g, 5r, and 5b are each structured using an organic material that is individually selected.

Particularly in this case, the transfer layer 5 forms a light emitting layer containing multiple components of a host material and a luminescent dopant material, and is obtained by simultaneously evaporating those material components from different evaporation boats and co-depositing them on the support substrate 3 under a vacuum condition. It is important for the host material and the luminescent dopant material constituting the transfer layer 5 to be selected so that a difference between sublimation temperatures of the host material and the dopant material falls within a predetermined range.

It should be noted that though the range of the difference between the sublimation temperatures of the materials is set for each emission color, it is desirable to select the host material and the luminescent dopant material such that the difference between the sublimation temperatures of the materials in the transfer layers 5g, 5r, and 5b of the respective colors become as small as possible.

In a case where a sublimation temperature of the host material at an atmospheric pressure is represented as T sub-H(° C.) and a sublimation temperature of the dopant material at the atmospheric pressure is represented as T sub-D(° C.), a difference between the sublimation temperatures of each transfer layer 5g, 5b, or 5r (T sub-H)−(T sub-D) is desirably set as follows.

That is, in the case of the green transfer layer 5g, when the sublimation temperature of the host material at the atmospheric pressure is T sub-H(° C.) and the sublimation temperature of the dopant material at the atmospheric pressure is T sub-D(° C.), the host material and the dopant material are selected within a range of Equation (1) below, desirably within a range of Equation (2) below, and more desirably within a range of Equation (3) below.

−65(° C.)≦(T sub-H)−(T sub-D)≦89(° C.) (1)

−33(° C.)≦(T sub-H)−(T sub-D)≦56(° C.) (2)

−28(° C.)≦(T sub-H)−(T sub-D)≦56(° C.) (3)

Further, in the case of the red transfer layer 5r, when the sublimation temperature of the host material at the atmospheric pressure is T sub-H(° C.) and the sublimation temperature of the dopant material at the atmospheric pressure is T sub-D(° C.), the host material and the dopant material are selected within a range of Equation (4) below, desirably within a range of Equation (5) below, and more desirably within a range of Equation (6) below.

−111(° C.)≦(T sub-H)−(T sub-D)≦78(° C.) (4)

−95(° C.)≦(T sub-H)−(T sub-D)≦51(° C.) (5)

−95(° C.)≦(T sub-H)−(T sub-D)≦25(° C.) (6)

The above values are obtained from luminescent properties of OLEDs as shown in examples described later. It should be noted that in a case where some kinds of materials are used for each of the host material and the dopant material that constitute the transfer layer 5, it is only required that each mass average value of sublimation temperatures of the materials under the atmospheric pressure is used as the sublimation temperature of the host material T sub-H(° C.) or the sublimation temperature of the dopant material T sub-D(° C.).

(2. Method of Manufacturing Display Apparatus)

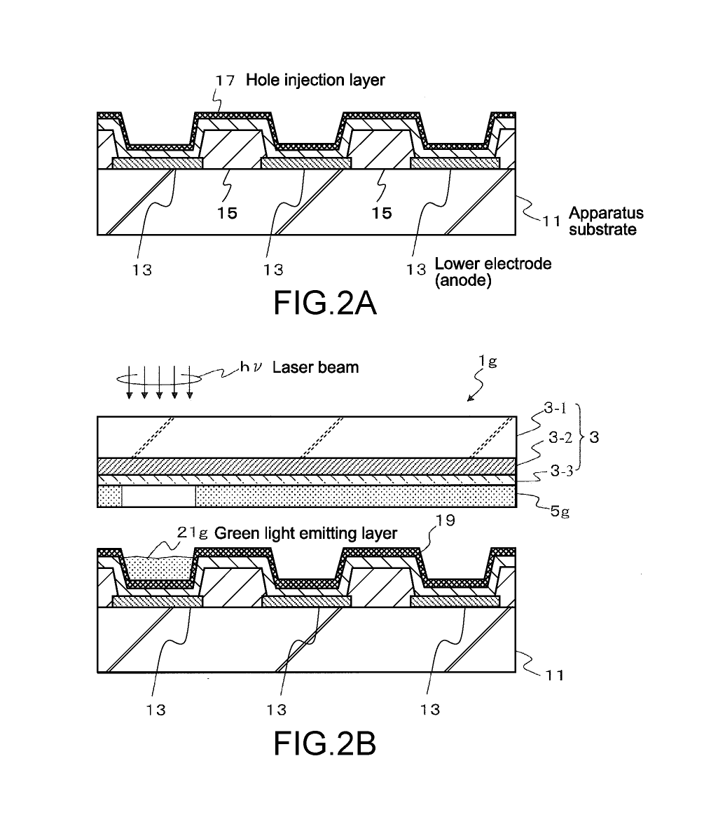

Next, a method of manufacturing a display apparatus that uses the transfer substrate 1 having the structure described above will be described with reference to cross-sectional process views of FIGS. 2 to 5. Here, manufacturing procedure for a display apparatus in which OLEDs of respective colors are formed on an apparatus substrate 11 will be described.

First, as shown in FIG. 2A, the apparatus substrate 11 is prepared. The apparatus substrate 11 is assumed to be a TFT (Thin Film Transistor) substrate obtained by forming TFTs for driving pixels on a glass, silicon, or plastic substrate.

Next, a lower electrode 13 used as an anode (or cathode) is patterned on each of the pixels formed on the apparatus substrate 11.

It is assumed that the lower electrode 13 is patterned to a shape appropriate for a driving method for the display apparatus manufactured in this embodiment. For example, in a case where the driving method for the display apparatus is a passive matrix method, the lower electrode 13 is formed in stripes in which the plurality of pixels are consecutive. On the other hand, in a case where the driving method for the display apparatus is an active matrix method in which each pixel is provided with a TFT, the lower electrode 13 is patterned so as to correspond to the pixels in an array, and is connected to the TFTs provided to the pixels via contact holes (not shown) formed in an interlayer insulating film that covers the TFTs.

Further, an appropriate material for the lower electrode 13 is selected and used depending on a light extraction method in the display apparatus manufactured in this embodiment. Specifically, in a case where the display apparatus is of a top-emission type in which emission light is extracted from a side opposite to the apparatus substrate 11 side, the lower electrode 13 is formed of a high reflective material. On the other hand, in a case where the display apparatus is of a transmissive or dual-sided emission type in which emission light is extracted from the apparatus substrate 11 side, the lower electrode 13 is formed of a light transmissive material.

In this embodiment, a top-emission type display apparatus in which an upper electrode 29 is a cathode and the lower electrode 13 is an anode is used, for example. In this case, the lower electrode 13 is formed of a conductive material having a high reflectance, such as silver (Ag), aluminum (Al), chromium (Cr), iron (Fe), cobalt (Co), nickel (Ni), copper (Cu), tantalum (Ta), tungsten (W), platinum (Pt), and gold (Au), and their alloy.

It should be noted that in a case where the display apparatus is of the top-emission type and the lower electrode 13 is used as a cathode, the lower electrode 13 is formed of a conductive material having a small work function. As such a conductive material, an alloy of an active metal such as lithium (Li), magnesium (Mg), and calcium (Ca) and a metal such as Ag, Al, and indium (In), or a structure in which those metals are laminated is used.

On the other hand, in a case where the display apparatus is of the transmissive or dual-sided emission type and the lower electrode 13 is used as an anode, the lower electrode 13 is formed of a conductive material having a high transmittance, such as an ITO (Indium-Tin-Oxide) and an IZO (Indium-Zinc-Oxide).

It should be noted that in a case where the active matrix method is employed as the driving method for the display apparatus manufactured in this embodiment, it is desirable to form a top-emission type display apparatus in order to ensure an aperture ratio of the OLEDs.

Then, after the lower electrode 13 (anode, in this case) as described above is formed, an insulating film 15 is patterned so as to cover a circumference of the lower electrode 13. Accordingly, portions in which the lower electrode 13 is exposed from windows formed on the insulating film 15 are assumed to be pixel areas in which the OLEDs are provided. The insulating film 15 is structured using an organic insulating material such as polyimide and photoresist or an inorganic insulating material such as silicon oxide.

Subsequently, a hole injection layer 17 is formed as a common layer for covering the lower electrode 13 and the insulating film 15. The hole injection layer 17 is formed of a hole injection material generally used, and for example, a film of m-MTDATA (4,4,4-tris(3-methylphenylphenylamino)triphenylamine is formed by vapor deposition in a thickness of 10 nm.

Then, a hole transport layer 19 is formed as a common layer for covering the hole injection layer 17. The hole transport layer 19 is formed of a hole transport material generally used, and for example, a film of α-NPD(4,4-bis(N-1-naphthyl-N-phenylamino)biphenyl) is formed by vapor deposition in a thickness of 35 nm. It should be noted that as a general hole transport material that constitutes the hole transport layer 19, a benzidine derivative, a styrylamine derivative, a triphenylmethane derivative, a hydrazone derivative, and the like are used.

Further, each of the hole injection layer 17 and the hole transport layer 19 above may be formed as a laminated structure including a plurality of layers.

Next, as shown in FIG. 2B, a green light emitting layer 21g is patterned above the lower electrode 13 in a part of pixels by transferring the green transfer layer 5g by the thermal transfer method.

In this case, in a vacuum bonding chamber subjected to nitrogen purge, the green transfer substrate 1g described with reference to FIG. 1 is first arranged so as to be opposed to the apparatus substrate 11 on which the layers including the hole transport layer 19 are formed. Specifically, the green transfer substrate 1g and the apparatus substrate 11 are arranged so that the green transfer layer 5g faces the hole transport layer 19. Then, the apparatus substrate 11 and the green transfer substrate 1g are brought into intimate contact with each other after the pressure of the vacuum bonding chamber is sufficiently reduced.

In such a state, a laser beam hν having a wavelength of 800 nm is applied from the green transfer substrate 1g side, for example. In this case, spot irradiation using the laser beam hν is selectively performed on portions corresponding to pixels forming green light emitting diodes.

Accordingly, the laser beam hr (→hν) is caused to be absorbed by the heat-generating layer 3-2 formed as the photothermal conversion layer, and using that heat, the green transfer layer 5g is thermally transferred to the apparatus substrate 11 side. Thus, the green light emitting layer 21g is patterned by thermally transferring the green transfer layer 5g on the hole transport layer 19 formed on the apparatus substrate 11 with excellent positional accuracy.

In the thermal transfer by the irradiation of the laser beam hν as described above, it is desirable to adjust a concentration gradient of the materials constituting the green transfer layer 5g on the transfer substrate 1g side by, for example, an irradiation energy of the laser beam hν. Specifically, by setting the irradiation energy to be relatively high, the green light emitting layer 21g is formed as a mixed layer in which the materials constituting the green transfer layer 5g are substantially uniformly mixed.

Further, in this process, it is important to perform the irradiation of the laser beam hν such that the portion above the lower electrode 13, which is exposed from the insulating film 15 and at which the green light emitting diode is to be formed (pixel area), is completely covered by the green light emitting layer 21g.

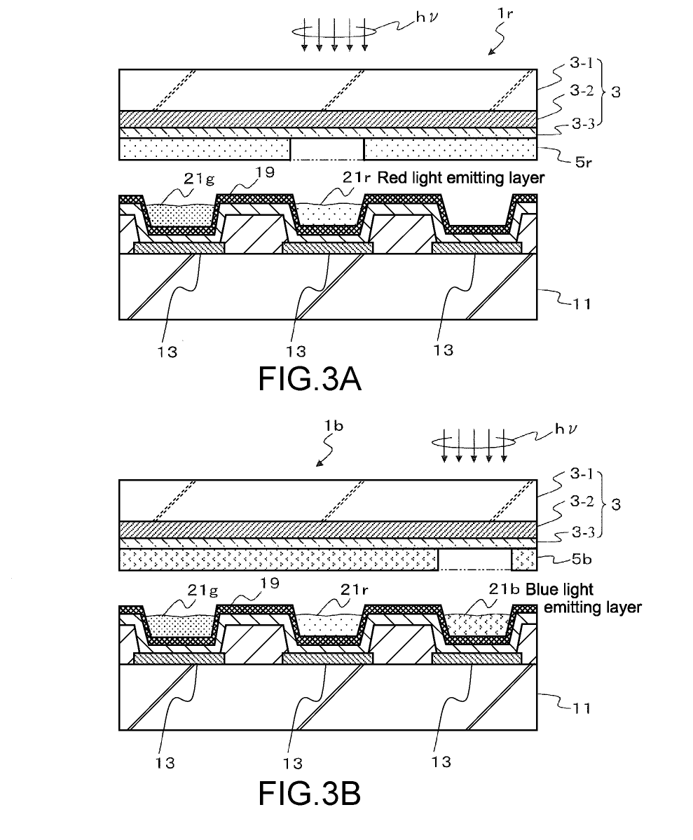

Subsequently, as shown in FIGS. 3A and 3B, a red light emitting layer 21r and a blue light emitting layer 21b are sequentially patterned on portions above the lower electrode 13 in the other pixels in which the green light emitting layer 21g is not formed. The red light emitting layer 21r and the blue light emitting layer 21b are sequentially formed by the thermal transfer by the irradiation of the laser beam hν, as in the case of the green light emitting layer 21g described above.

It should be noted that the process of the thermal transfer that is repeated three times as described above may be repeated in any order. Moreover, the heat source of the thermal transfer is not limited to the irradiation of the laser beam hν, and heating with a heater may be applicable. However, a rate of temperature rise of the transfer layer 5 can be increased using the laser beam hν, and accordingly a difference between the sublimation temperatures of materials is not large in a case where the transfer layer 5 is formed of a plurality of materials, with the result that the laser beam hν is desirably applied.

It should be noted that the formation of the blue light emitting layer 21b is not limited to the application of the thermal transfer, and may be formed as a common layer for all the pixels by vapor deposition.

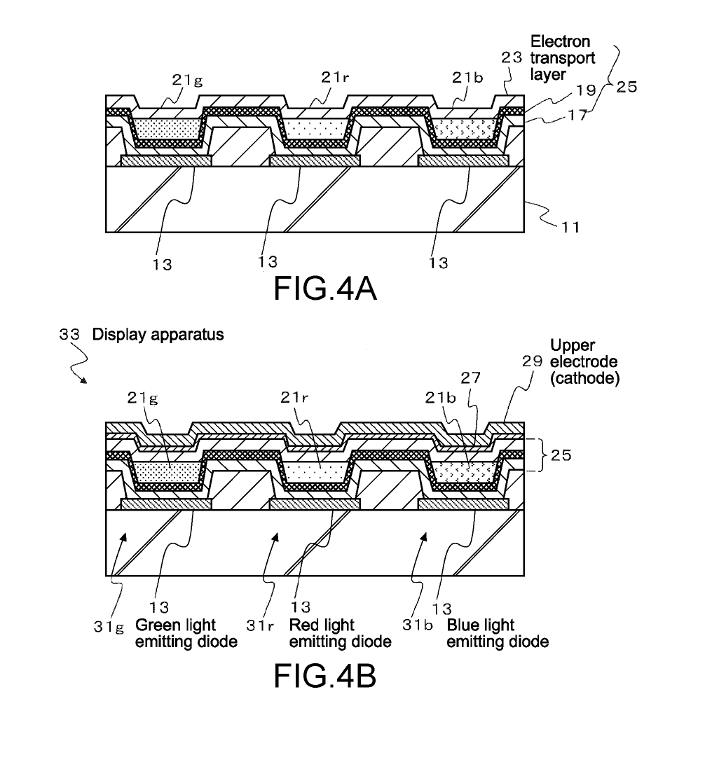

After the processes described above, as shown in FIG. 4A, an electron transport layer 23 is formed so as to cover the entire surface of the apparatus substrate 11 on which the light emitting layers of the respective colors 21g, 21r, and 21b are formed. The electron transport layer 23 is formed by vapor deposition as a common layer on the entire surface of the apparatus substrate 11.

Such an electron transport layer 23 is formed of an electron transport material generally used, and for example, a film of 8-hydroxyquinoline aluminum (Alq3) is formed by vapor deposition in a thickness of about 20 nm.

By the hole injection layer 17, the hole transport layer 19, the light emitting layers of the respective colors, and the electron transport layer 23 formed up to here, an organic layer 25 is formed.

Next, as shown in FIG. 4B, an electron injection layer 27 is formed on the electron transport layer 23. The electron injection layer 27 is formed by vapor deposition as a common layer on the entire surface of the apparatus substrate 11. Such an electron injection layer 27 is formed of an electron injection material generally used, and for example, a film of lithium fluoride (LiF) is formed to be a thickness of about 0.3 nm (vapor deposition rate to 0.01 nm/sec) by vacuum vapor deposition.

Then, the upper electrode 29 is formed on the electron injection layer 27. The upper electrode 29 is used as a cathode when the lower electrode 13 serves as an anode, and is used as an anode when the lower electrode 13 serves as a cathode. In this case, the upper electrode 29 is formed as a cathode. It should be noted that in the case where the lower electrode 13 is a cathode and the upper electrode 29 is an anode, the lamination order of the layers laminated between the lower electrode 13 and the upper electrode 29 is reversed.

Further, in the case where the display apparatus manufactured in this embodiment is of the passive matrix method, the upper electrode 29 is formed in stripes that intersect with the stripes of the lower electrode 13, for example. On the other hand, in the case where the display apparatus manufactured in this embodiment is of the active matrix method, the upper electrode 29 is formed in a shape of a uniform film to cover the entire surface of the apparatus substrate 11, and is used as a common electrode for the pixels. In this case, an auxiliary electrode (not shown) is formed on the same layer as the lower electrode 13 and is connected to the upper electrode 29, with the result that it is possible to obtain a structure in which a voltage drop of the upper electrode 29 is prevented.

In an intersection portion of the lower electrode 13 and the upper electrode 29 in which the organic layer 25 including each of the light emitting layers of the respective colors 21g, 21r, and 21b is sandwiched therebetween, a green light emitting diode 31g, a red light emitting diode 31r, or a blue light emitting diode 31b is formed.

It should be noted that a material appropriate for the upper electrode 29 is selected and used depending on the light extraction method of the display apparatus manufactured in this embodiment. That is, in a case where the display apparatus is a top-emission type or dual-sided emission type display apparatus in which emission light from the light emitting layers of the respective colors 21g, 21r, and 21b is extracted from the side opposite to the apparatus substrate 11 side, the upper electrode 29 is formed of a light transmissive material or a semi-transmissive material. On the other hand, in a case where the display apparatus is of a bottom-emission type in which emission light is extracted from only the apparatus substrate 11 side, the upper electrode 29 is formed of high reflective material.

Here, since the display apparatus is of the top-emission type and the lower electrode 13 is used as an anode, the upper electrode 29 is used as a cathode. In this case, the upper electrode 29 is formed of a material having excellent light transmissive properties, which is selected from those having a small work function exemplified in the process of forming the lower electrode 13 so that electrons are effectively injected into the organic layer 25.

Thus, the upper electrode 29 is formed as a common cathode made of MgAg in a thickness of 10 nm by vacuum vapor deposition. In this case, the upper electrode 29 is deposited by a deposition method in which energies of deposition particles are small to the extent where the energies do not affect a ground layer, for example, by vapor deposition or CVD (Chemical Vapor Deposition).

Further, in the case where the display apparatus is of the top-emission type, it is desirable to design the display apparatus such that an intensity of extracted light is increased by forming a resonator structure between the upper electrode 29 and the lower electrode 13 due to the upper electrode 29 being made of a semi-transmissive material.

Furthermore, in the case where the display apparatus is of the transmissive type and the upper electrode 29 is used as a cathode, the upper electrode 29 is formed of a conductive material having a small work function and a high reflectance. In the case where the display apparatus is of the transmissive type and the upper electrode 29 is used as an anode, the upper electrode 29 is formed of a conductive material having a high reflectance.

After the OLEDs of the respective colors 31g, 31r, and 31b are formed as described above, the OLEDs of the respective colors 31g, 31r, and 31b are sealed. Here, a protective film (not shown) is formed so as to cover the upper electrode 29. The protective film is formed to prevent moisture from reaching the organic layer 25 and is formed of a material having a low water permeability and water absorbency in a sufficient thickness. Moreover, in the case where the display apparatus manufactured in this embodiment is of the top-emission type, the protective film is made of a material that transmits light generated by the light emitting layers of the respective colors 21g, 21r, and 21b, and ensures transmittance of about 80%, for example.

The protective film as described above may be formed of an insulating material, and in a case where the display apparatus manufactured in this embodiment is an active matrix display apparatus and the upper electrode 29 is provided as a common electrode that covers the entire surface of the apparatus substrate 11, the protective film may be formed of a conductive material. In a case where the protective material is formed of the conductive material, a transparent conductive material such as an ITO and an IZO is used.

It should be noted that it is desirable for each of the layers covering the light emitting layers of the respective colors 21g, 21r, and 21b to be continuously formed in a shape of a uniform film in a single deposition apparatus without using a mask and being atmospherically exposed.

In addition, a protective substrate is bonded to the apparatus substrate 11 on which the protective film is formed as described above via a resin material for bonding on the protective film side. As the resin material for bonding, a UV-curable resin is used, for example. As the protective substrate, a glass substrate is used, for example. It should be noted that the display apparatus manufactured in this embodiment is a top-emission type display apparatus, it may be indispensable for the resin material for bonding and the protective substrate to be made of a light transmissive material.

Though the above processes, a full-color display apparatus 33 in which the light emitting diodes of the respective colors 31g, 31r, and 31b are arranged on the apparatus substrate 11 is completed.

As described above, in the method of manufacturing the display apparatus according to this embodiment, the difference between the sublimation temperatures of the host material and the luminescent dopant material that constitute the transfer layer is set within the predetermined range when the transfer layer on the transfer substrate side is thermally transferred to the apparatus substrate side to form the light emitting layer. Therefore, in the thermal transfer, the host material and the luminescent dopant material that constitute the transfer layer can be sublimated nearly at the same time. Accordingly, the light emitting layer in which the host material and the dopant material are uniformly distributed in a depth direction is formed by the thermal transfer, and thus the OLED in which an excellent carrier balance is ensured can be obtained.

Consequently, according to the embodiment of the present invention, an OLED with an excellent carrier balance and stable luminescent properties can be obtained even when a light emitting layer is formed by applying a thermal transfer method, with the result that a display apparatus with excellent display properties can be obtained as described in examples described later.

(3. Circuit Structure of Display Apparatus)

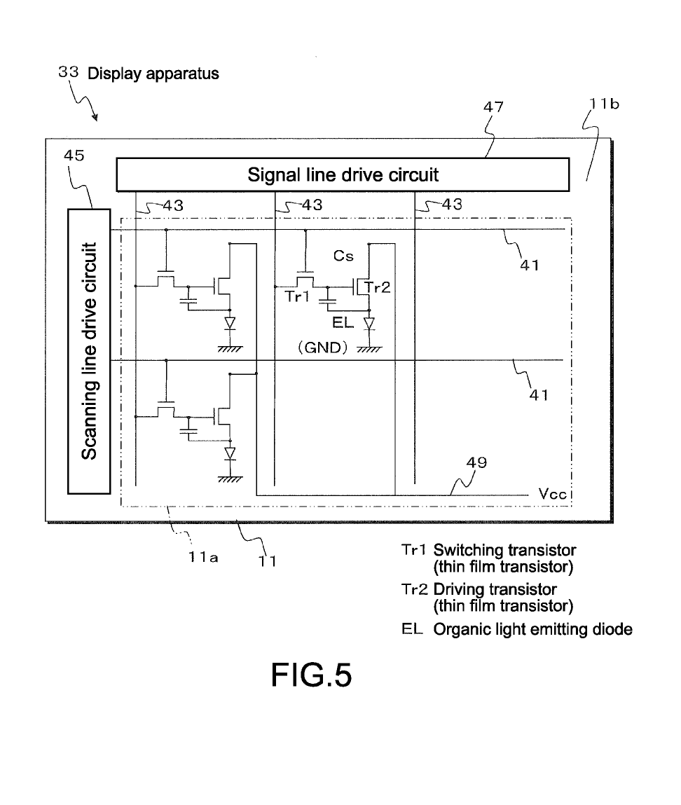

FIG. 5 is a diagram showing an example of a circuit structure of an active matrix display apparatus using the OLEDs described above. As shown in FIG. 5, a display area 11a and its peripheral area 11b are provided on the apparatus substrate 11. The display area 11a is provided with a plurality of scanning lines 41 and a plurality of signal lines 43 that are arranged vertically and horizontally thereon, and is structured as a pixel array portion in which pixels are provided so as to correspond to respective intersecting portions of the scanning lines 41 and the signal lines 43. Arranged in the peripheral area 11b are a scanning line drive circuit 45 that scans and drives the scanning lines 41 and a signal line drive circuit 47 that supplies video signals in accordance with luminance information (that is, input signals) to the signal lines 43.

A pixel circuit provided in each of the intersecting portions between the scanning lines 41 and the signal lines 43 includes, for example, a switching thin film transistor Tr1, a driving thin film transistor Tr2, a storage capacitor Cs, and an organic light emitting diode EL. Due to the drive of the scanning line drive circuit 45, video signals written from the signal lines 43 via the switching thin film transistor Tr1 are stored in the storage capacitor Cs, and a current in accordance with the stored signal amount is supplied to the organic light emitting diode EL from the driving thin film transistor Tr2. Accordingly, the organic light emitting diode EL emits light with luminance in accordance with that current value. It should be noted that the driving thin film transistor Tr2 and the storage capacitor Cs are connected to a common power supply line (Vcc) 49.

It should be noted that the structure of the pixel circuit as described above is merely an example, and the pixel circuit may be structured by providing a capacitor element or other transistors therein as appropriate. Moreover, drive circuits necessary in accordance with a change in the pixel circuit are added to the peripheral area 11b.

(4. Application Examples)

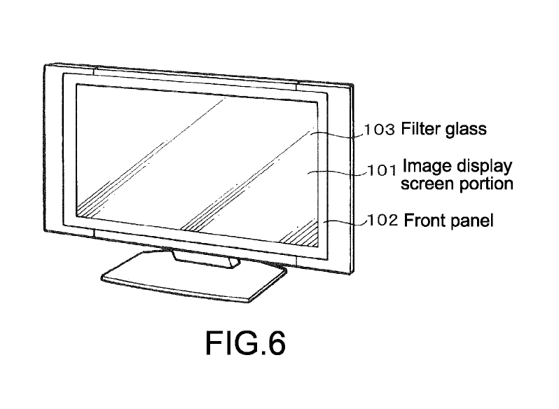

Descriptions will be made on examples of an electronic apparatus that uses the display apparatus according to the above-mentioned embodiment of the present invention as a display panel with reference to FIGS. 6 to 10. The display panel (display apparatus) having the structure described above can be used as a display panel of a display portion of an electronic apparatus. The display panel is applicable to a display portion of electronic apparatuses in all fields, on which video signals input to the electronic apparatuses or generated in the electronic apparatuses are displayed as images. Examples of the electronic apparatuses include a digital camera, a laptop personal computer, a mobile terminal apparatus such as a cellular phone, and a video camera. Hereinafter, examples of the electronic apparatuses to which the embodiment of the present invention is applied will be described.

FIG. 6 is a perspective view showing a television to which the embodiment of the present invention is applied. The television of this application example includes an image display screen portion 101 constituted of a front panel 102, a filter glass 103, and the like. The television is produced using the display apparatus according to the embodiment of the present invention as the image display screen portion 101.

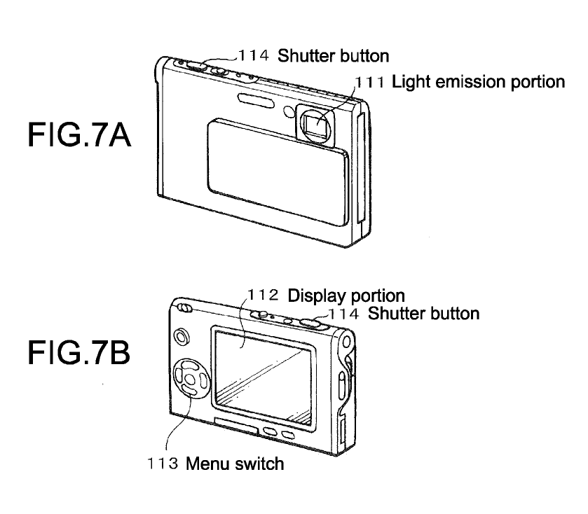

FIG. 7 are views each showing a digital camera to which the embodiment of the present invention is applied, in which FIG. 7A is a perspective view seen from a front side thereof and FIG. 7B is a perspective view seen from a backside thereof. The digital camera of this application example includes a light emission portion for flash 111, a display portion 112, a menu switch 113, a shutter button 114, and the like. The digital camera is produced using the display apparatus according to the embodiment of the present invention as the display portion 112.

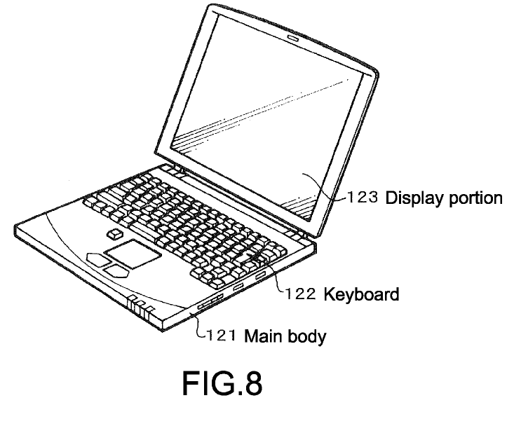

FIG. 8 is a perspective view showing a laptop personal computer to which the embodiment of the present invention is applied. The laptop personal computer of this application example includes a main body 121, a keyboard 122 that is operated in inputting letters or the like, a display portion 123 for displaying images, and the like, and is produced using the display apparatus according to the embodiment of the present invention as the display portion 123.

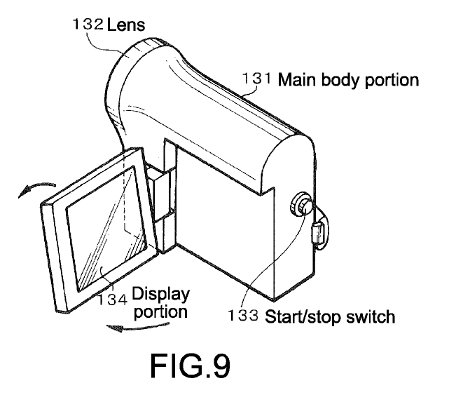

FIG. 9 is a perspective view showing a video camera to which the embodiment of the present invention is applied. The video camera of this application example includes a main body portion 131, a lens 132 for photographing a subject, the lens 132 being provided on a side surface seen in the figure, a start/stop switch for photographing 133, a display portion 134, and the like. The video camera is produced using the display apparatus according to the embodiment of the present invention as the display portion 134.

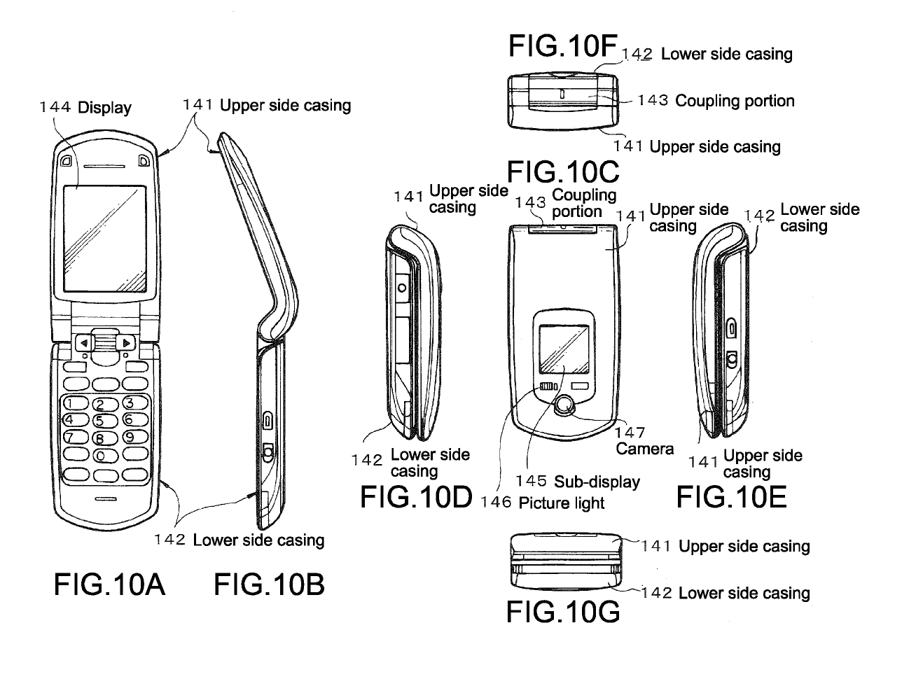

FIG. 10 are views showing a mobile terminal apparatus, for example, a cellular phone, to which the embodiment of the present invention is applied, in which FIG. 10A is a front view thereof in an open state, FIG. 10B is a side view thereof, FIG. 10C is a front view thereof in a closed state, FIG. 10D is a left-hand side view thereof, FIG. 10E is a right-hand side view thereof, FIG. 10F is a top view thereof, and FIG. 10G is a bottom view thereof. The cellular phone of this application example includes an upper side casing 141, a lower side casing 142, a coupling portion (in this case, hinge portion) 143, a display 144, a sub-display 145, a picture light 146, a camera 147, an the like, and is produced using the display apparatus according to the embodiment of the present invention as the display 144 and the sub-display 145.

### EXAMPLES

With regard to the formation of the light emitting layers, in which the thermal transfer is applied, an OLED that emits green light and an OLED that emits red light were produced while changing the host material and the luminescent dopant material as follows. A current efficiency and a half-life of luminance of each of the obtained OLEDs were measured, and comparison values obtained by comparing the above OLEDs and OLEDs in which light emitting layers are formed by vapor deposition were calculated.

### Examples 1 to 16

### See Table 1 Below

A thermal transfer using laser irradiation as a heat source was applied and the OLED that emits green light was produced as follows.

(1) Production of Transfer Substrate

An anti-reflective layer made of silicon with a thickness of 40 nm and a photothermal conversion layer made of molybdenum (Mo) with a thickness of 200 nm were sequentially formed on a glass substrate having a thickness of 1 mm (substrate body 3-1) by a normal sputtering method, to thereby form a heat-generating layer 3-2 having a laminated structure. Next, a protective layer 3-3 made of silicon nitride (SiNₓ) was formed on the photothermal conversion layer (heat-generating layer 3-2) in a thickness of 50 nm by CVD. Then, a green transfer layer 5g in which a host material was mixed with 5 wt % of a guest material of green luminance was formed on the protective layer 3-3 in a thickness of 30 nm by vapor deposition, thus obtaining a transfer substrate 1g. The host materials and the guest materials are shown in Table 1 below.

(2) Formation on Apparatus Substrate Side

On the other hand, a lower electrode 13 of a two-layer structure in which an APC (Ag-Pd-Cu) layer serving as a silver alloy layer (thickness of 120 nm) and a transparent conductive layer made of ITO (thickness of 10 nm) were formed in the stated order was formed as an anode on an apparatus substrate 11. Further, as a hole injection layer 17, a film of m-MTDATA was formed on a surface of the lower electrode 13 in a thickness of 25 nm by vapor deposition. Then, as a hole transport layer 19, a film of α-NPD was formed in a thickness of 30 nm by vapor deposition.

(3) Thermal Transfer

Next, in a vacuum bonding chamber subjected to nitrogen purge, the transfer substrate 1g produced in the process (1) and the apparatus substrate 11 in which the layers including the hole transport layer 19 were formed in the process (2) were arranged with the green transfer layer 5g and the hole transport layer 19 being opposed to each other. After that, the vacuum bonding chamber and a space between the substrates were evacuated to reach a degree of vacuum of 1×10⁻³ Pa. In this state, by applying a laser beam hν having a wavelength of about 800 nm from the transfer substrate 1g side, the green transfer layer 5g was thermally transferred from the transfer substrate 1g to the apparatus substrate 11 side, thus forming a green light emitting layer 21g. A spot size of the laser beam hν was set to 300 μm×10 μm. The laser beam hν was used for scanning in a direction orthogonal to a longitudinal direction of the laser beam. An energy density was set to 2.6E-3 (2.6×10⁻³) mJ/μm².

(4) Formation of Upper Layer

After the green light emitting layer 21g was formed by transfer, the vacuum bonding chamber was subjected to nitrogen purge and the apparatus substrate 11 was taken out. Then, the apparatus substrate 11 was moved in a vacuum deposition apparatus, and as an electron transport layer 23, a film of 8-hydroxyquinoline aluminum (Alq3) was formed in a thickness of about 20 nm by vapor deposition. Subsequently, a film of LiF was formed as an electron injection layer 27 in a thickness of about 0.3 nm by vapor deposition, and then, as a cathode to serve as an upper electrode 29, a film of an Mg/Ag alloy (ratio by weight of 90:10) was formed in a thickness of 10 nm by co-deposition. A protective film made of silicon nitride was further formed in a thickness of 1 μm by CVD, a UV-curable resin was applied in a thickness of 30 μm, and ultraviolet rays were irradiated with a glass plate of 1 mm being bonded to thereby cure the resin, thus obtaining a green light emitting diode 31g by applying the thermal transfer in which the laser beam hν was used as a heat source.

### Examples 17 to 32

### See Table 2 Below

A thermal transfer using heating with a heater as a heat source was applied and the OLED that emits green light was produced. Processes in Examples 17 to 32 were the same as those performed in Examples 1 to 16 except that the thermal transfer due to heating with a heater was performed in the process (3) in Examples 1 to 16. In the thermal transfer, a temperature of heating due to the heater was set to a lowest temperature at which the transfer could be performed (290° C.), and a temperature of the apparatus substrate was controlled to be 20° C. by cooling water in order to prevent the heat from being transmitted to the apparatus substrate. It should be noted that the host materials and the guest materials of green luminance that constitute the light emitting layer are shown in Table 2 below.

### Examples 33 to 56

### See Table 3 Below

A thermal transfer using laser irradiation as a heat source was applied and an OLED that emits red light was produced.

Processes in Examples 33 to 56 were the same as those performed in Examples 1 to 16 except that a red transfer layer 5r in which a host material was mixed with 5 wt % of a guest material of red luminance was formed in a thickness of 30 nm by vapor deposition and thus a transfer substrate 1r was obtained in the process (1) in Examples 1 to 16. It should be noted that the host materials and the guest materials of red luminance that constitute the light emitting layer are shown in Table 3 below.

### Examples 57 to 72

### See Table 4 Below

A thermal transfer using heating with a heater as a heat source was applied and the OLED that emits red light was produced. Processes in Examples 57 to 72 were the same as those performed in Examples 33 to 56 except that the thermal transfer due to heating with a heater was performed in the process of the thermal transfer in Examples 33 to 56. In the thermal transfer, a temperature of heating due to the heater was set to a lowest temperature at which the transfer could be performed (290° C.), and a temperature of the apparatus substrate was controlled to be 20° C. by cooling water in order to prevent the heat from being transmitted to the apparatus substrate. It should be noted that the host materials and the guest materials of red luminance that constitute the light emitting layer are shown in Table 4 below.

(Characteristic Evaluation)

Tables 1 to 4 below shows the host materials and the dopant materials used in Examples 1 to 72, their sublimation temperatures (T sub-H) and (T sub-D), and a difference thereof (T sub-H)−(T sub-D). Further, a current efficiency and a half-life of luminance were measured on the OLEDs obtained in Examples 1 to 72, and those measured values are shown as a ratio with respect to values of OLEDs in which light emitting layers were formed by vapor deposition. It should be noted that the sublimation temperature of each of the materials was set for a point at which a weight reduction of 0.5% was caused by Thermogravimetry (TG). In this case, heating was started from room temperature and thus the temperature was raised using a program of a temperature rise of 10° C./min.

TABLE 1
(Green) Laser irradiation

| | | | | | | Ratio of | Ratio of |
|---|---|---|---|---|---|---|---|
| | | | | | | current | half life of |
| | | | | | | efficiency | luminance |
| | | | | | | (transfer/vapor | (transfer/vapor |
| | Host | Dopant | Tsub-H | Tsub-D | [Tsub-H] − | deposition)@ | deposition)@ |
| | material | material | (° C.) | (° C.) | [Tsub-D] | 80 mA/cm2 | 80 mA/cm2 |
| Example 1 | ADN | Coumarin 6 | 322 | 349 | −27 | 0.91 | 0.63 |
| Example 2 | | Dopant a | | 354 | −32 | 0.93 | 0.60 |
| Example 3 | | Dopant b | | 387 | −65 | 0.60 | 0.22 |
| Example 4 | | Dopant c | | 425 | −103 | 0.43 | 0.11 |
| Example 5 | Host A | Coumarin 6 | 354 | 349 | 5 | 0.95 | 0.65 |
| Example 6 | | Dopant a | | 354 | 0 | 0.95 | 0.63 |
| Example 7 | | Dopant b | | 387 | −33 | 0.90 | 0.59 |
| Example 8 | | Dopant c | | 425 | −71 | 0.55 | 0.19 |
| Example 9 | Host B | Coumarin 6 | 397 | 349 | 48 | 0.93 | 0.64 |
| Example 10 | | Dopant a | | 354 | 43 | 0.94 | 0.63 |
| Example 11 | | Dopant b | | 387 | 10 | 0.96 | 0.67 |
| Example 12 | | Dopant c | | 425 | −28 | 0.94 | 0.62 |
| Example 13 | Host C | Coumarin 6 | 443 | 349 | 94 | 0.56 | 0.22 |
| Example 14 | | Dopant a | | 354 | 89 | 0.72 | 0.50 |
| Example 15 | | Dopant b | | 387 | 56 | 0.94 | 0.65 |
| Example 16 | | Dopant c | | 425 | 18 | 0.95 | 0.65 |

TABLE 2
(Green) Heating by heater

| | | | | | | Ratio of | Ratio of |
|---|---|---|---|---|---|---|---|
| | | | | | | current | half-life of |
| | | | | | | efficiency | luminance |
| | | | | | | (transfer/vapor | (transfer/vapor |
| | Host | Dopant | Tsub-H | Tsub-D | [Tsub-H] − | deposition)@ | deposition)@ |
| | material | material | (° C.) | (° C.) | [Tsub-D] | 80 mA/cm2 | 80 mA/cm2 |
| Example 17 | ADN | Coumarin 6 | 322 | 349 | −27 | 0.86 | 0.58 |
| Example 18 | | Dopant a | | 354 | −32 | 0.53 | 0.42 |
| Example 19 | | Dopant b | | 387 | −65 | 0.40 | 0.15 |
| Example 20 | | Dopant c | | 425 | −103 | 0.32 | 0.07 |
| Example 21 | Host A | Coumarin 6 | 354 | 349 | 5 | 0.91 | 0.61 |
| Example 22 | | Dopant a | | 354 | 0 | 0.90 | 0.59 |
| Example 23 | | Dopant b | | 387 | −33 | 0.47 | 0.39 |
| Example 24 | | Dopant c | | 425 | −71 | 0.32 | 0.13 |
| Example 25 | Host B | Coumarin 6 | 397 | 349 | 48 | 0.90 | 0.61 |
| Example 26 | | Dopant a | | 354 | 43 | 0.92 | 0.59 |
| Example 27 | | Dopant b | | 387 | 10 | 0.92 | 0.60 |
| Example 28 | | Dopant c | | 425 | −28 | 0.94 | 0.62 |
| Example 29 | Host C | Coumarin 6 | 443 | 349 | 94 | 0.34 | 0.15 |
| Example 30 | | Dopant a | | 354 | 89 | 0.42 | 0.33 |
| Example 31 | | Dopant b | | 387 | 53 | 0.80 | 0.45 |
| Example 32 | | Dopant c | | 425 | 18 | 0.88 | 0.55 |

TABLE 3
(Red) Laser irradiation

| | | | | | | Ratio of | Ratio of |
|---|---|---|---|---|---|---|---|
| | | | | | | current | half-life of |
| | | | | | | efficiency | luminance |
| | | | | | | (transfer/vapor | (transfer/vapor |
| | Host | Dopant | Tsub-H | Tsub-D | [Tsub-H] − | deposition)@ | deposition)@ |
| | material | material | (° C.) | (° C.) | [Tsub-D] | 80 mA/cm2 | 80 mA/cm2 |
| Example 33 | ADN | BSN | 322 | 433 | −111 | 0.63 | 0.59 |
| Example 34 | | Dopant d | | 356 | −34 | 0.74 | 0.73 |
| Example 35 | | Dopant e | | 464 | −142 | 0.49 | 0.51 |
| Example 36 | | Dopant f | | 363 | −41 | 0.71 | 0.69 |
| Example 37 | | Dopant g | | 390 | −68 | 0.72 | 0.68 |
| Example 38 | | Dopant h | | 400 | −78 | 0.70 | 0.66 |
| Example 39 | Host D | BSN | 369 | 433 | −64 | 0.73 | 0.69 |
| Example 40 | | Dopant d | | 356 | 13 | 0.75 | 0.70 |
| Example 41 | | Dopant e | | 464 | −95 | 0.70 | 0.68 |
| Example 42 | | Dopant f | | 363 | 6 | 0.73 | 0.70 |
| Example 43 | | Dopant g | | 390 | −21 | 0.70 | 0.72 |
| Example 44 | | Dopant h | | 400 | −31 | 0.77 | 0.68 |
| Example 45 | Host E | BSN | 381 | 433 | −52 | 0.69 | 0.66 |
| Example 46 | | Dopant d | | 356 | 25 | 0.68 | 0.70 |
| Example 47 | | Dopant e | | 464 | −83 | 0.73 | 0.70 |
| Example 48 | | Dopant f | | 363 | 18 | 0.70 | 0.72 |
| Example 49 | | Dopant g | | 390 | −9 | 0.75 | 0.70 |
| Example 50 | | Dopant h | | 400 | −19 | 0.72 | 0.69 |
| Example 51 | Host F | BSN | 441 | 433 | 8 | 0.70 | 0.72 |
| Example 52 | | Dopant d | | 356 | 85 | 0.51 | 0.52 |
| Example 53 | | Dopant e | | 464 | −23 | 0.72 | 0.69 |
| Example 54 | | Dopant f | | 363 | 78 | 0.63 | 0.61 |
| Example 55 | | Dopant g | | 390 | 51 | 0.72 | 0.70 |
| Example 56 | | Dopant h | | 400 | 41 | 0.71 | 0.69 |

TABLE 4
(Red) Heating by heater

| | | | | | | Ratio of | Ratio of |
|---|---|---|---|---|---|---|---|
| | | | | | | current | half-life of |
| | | | | | | efficiency | luminance |
| | | | | | | (transfer/vapor | (transfer/vapor |
| | Host | Dopant | Tsub-H | Tsub-D | [Tsub-H] − | deposition)@ | deposition)@ |
| | material | material | (° C.) | (° C.) | [Tsub-D] | 80 mA/cm2 | 80 mA/cm2 |
| Example 57 | ADN | BSN | 322 | 433 | −111 | 0.58 | 0.55 |
| Example 58 | | Dopant d | | 356 | −34 | 0.70 | 0.69 |
| Example 59 | | Dopant e | | 464 | −142 | 0.40 | 0.43 |
| Example 60 | | Dopant f | | 363 | −41 | 0.69 | 0.65 |
| Example 61 | | Dopant g | | 390 | −68 | 0.71 | 0.68 |
| Example 62 | | Dopant h | | 400 | −78 | 0.69 | 0.68 |
| Example 63 | Host D | Dopant d | 369 | 356 | 13 | 0.73 | 0.70 |
| Example 64 | | Dopant e | | 464 | −95 | 0.68 | 0.65 |
| Example 65 | | Dopant f | | 363 | 6 | 0.70 | 0.68 |
| Example 66 | Host E | Dopant d | 381 | 356 | 25 | 0.65 | 0.68 |
| Example 67 | | Dopant e | | 464 | −83 | 0.71 | 0.68 |
| Example 68 | | Dopant h | | 400 | −19 | 0.69 | 0.67 |
| Example 69 | Host F | Dopant d | 441 | 356 | 85 | 0.51 | 0.52 |
| Example 70 | | Dopant f | | 363 | 78 | 0.50 | 0.53 |
| Example 71 | | Dopant g | | 390 | 51 | 0.53 | 0.54 |
| Example 72 | | Dopant h | | 400 | 41 | 0.56 | 0.58 |

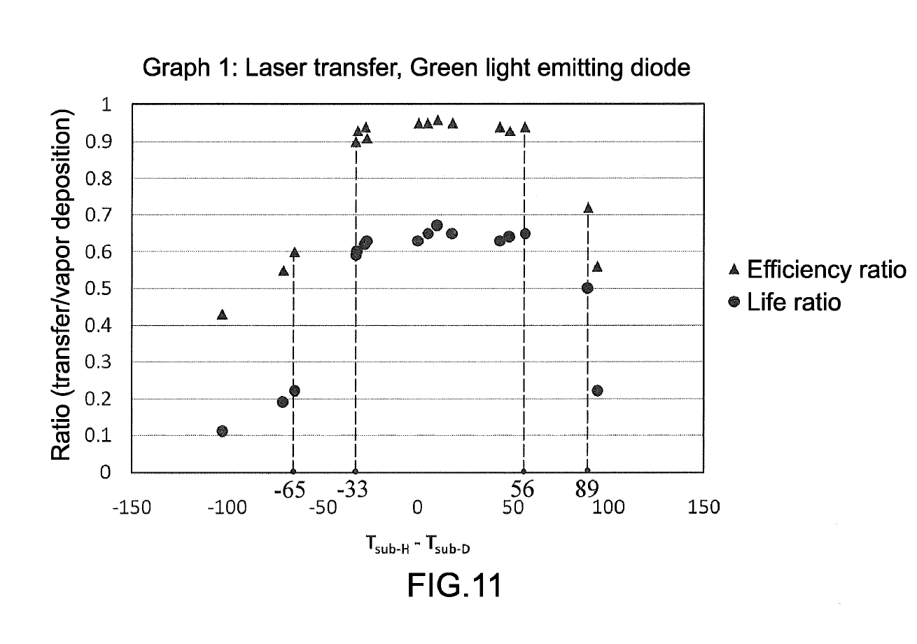

FIG. 11 is a graph showing a relationship between a ratio of the characteristics obtained by the measurement and a difference of sublimation temperatures (T sub-H)-(T sub-D) shown in Table 1. The following results were found from FIG. 11. In the thermal transfer for forming the light emitting layer of the OLED that emits green light, a ratio of luminous efficiency of 0.6 or more can be ensured by satisfying the range of the temperature difference of

−65(° C.)≦(T sub-H)−(T sub-D)≦89(° C.) (1)

when a temperature is raised at high-speed using a leaser beam as a heat source. Further, the ratio of luminous efficiency can be increased to 0.9 or more by satisfying the range of the temperature difference of

−33(° C.)≦(T sub-H)−(T sub-D)≦56(° C.) (2),

and a life ratio of 0.6 or more can also be ensured.

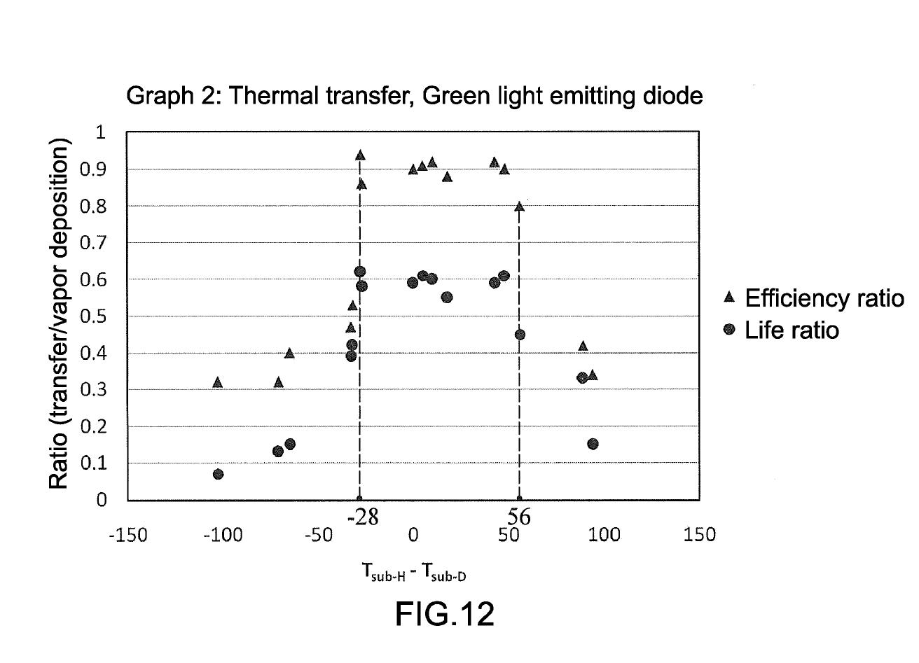

FIG. 12 is a graph showing a relationship between a ratio of the characteristics obtained by the measurement and a difference of sublimation temperatures (T sub-H)−(T sub-D) shown in Table 2. The following results were found from FIG. 12. In the thermal transfer for forming the light emitting layer of the OLED that emits green light, the ratio of luminous efficiency of 0.8 or more can be ensured by satisfying the range of the temperature difference of

−28(° C.)≦(T sub-H)−(T sub-D)≦56(° C.) (3)

even when the temperature is raised using a heater as a heat source. Further, the life ratio of about 0.6 can also be ensured.

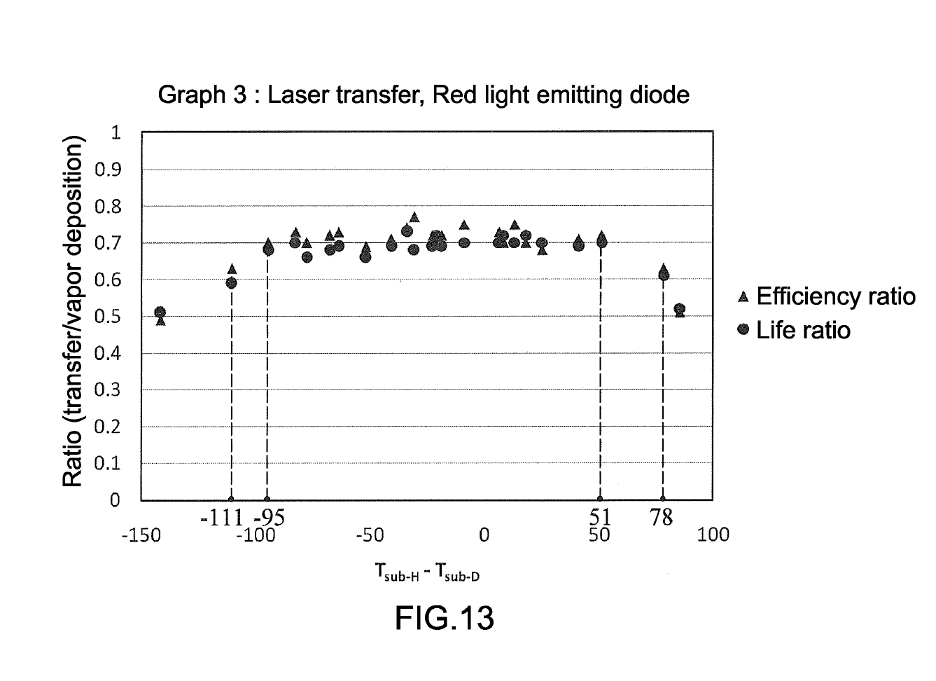

FIG. 13 is a graph showing a relationship between a ratio of the characteristics obtained by the measurement and a difference of sublimation temperatures (T sub-H)−(T sub-D) shown in Table 3. The following results were found from FIG. 13. In the thermal transfer for forming the light emitting layer of the OLED that emits red light, the ratio of luminous efficiency of 0.6 or more can be ensured by satisfying the range of the temperature difference of

−111(° C.)≦(T sub-H)−(T sub-D)≦78(° C.) (4)

when the temperature is raised at high-speed using a leaser beam as a heat source. Further, the ratio of luminous efficiency can be increased to about 0.7 by satisfying the range of the temperature difference of

−95(° C.)≦(T sub-H)−(T sub-D)≦51(° C.) (5),

and the life ratio of about 0.7 can also be ensured.

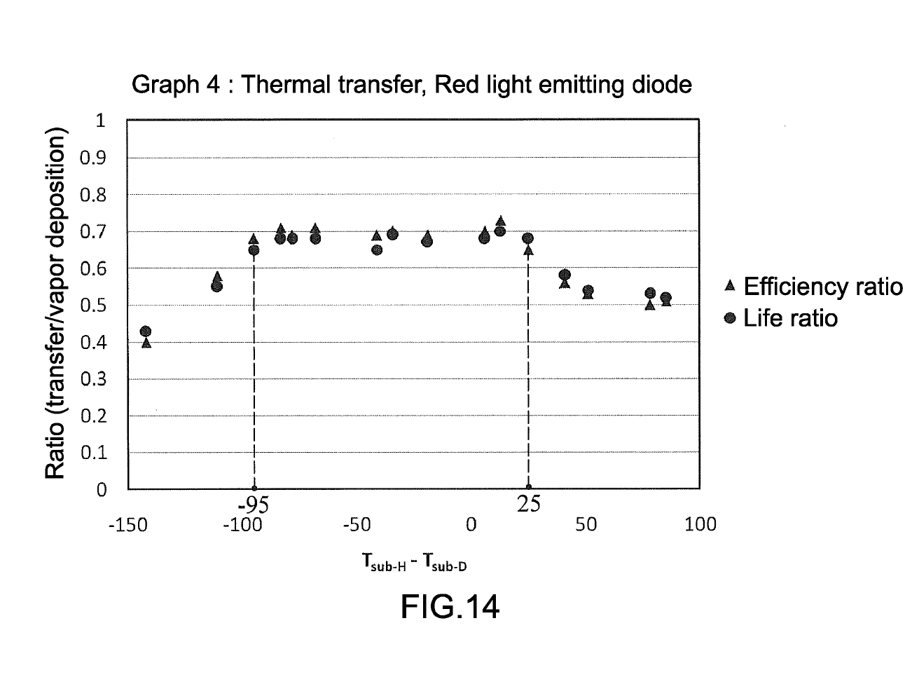

FIG. 14 is a graph showing a relationship between a ratio of the characteristics obtained by the measurement and a difference of sublimation temperatures (T sub-H)−(T sub-D) shown in Table 4. The following results were found from FIG. 14. In the thermal transfer for forming the light emitting layer of the OLED that emits red light, the ratio of luminous efficiency of 0.65 or more can be ensured by satisfying the range of the temperature difference of

−95(° C.)≦(T sub-H)−(T sub-D)≦25(° C.) (6)

even when the temperature is raised using a heater as a heat source. Further, the life ratio of 0.65 or more can also be ensured.

As the results of the evaluation described above, it was confirmed that the difference between the sublimation temperatures of the host material and the luminescent dopant material could be effectively used as guidelines for selecting and developing a luminescent material appropriate for transfer methods.

The present application contains subject matter related to that disclosed in Japanese Priority Patent Application JP 2008-326860 filed in the Japan Patent Office on Dec. 24, 2008, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A transfer substrate, comprising:
a support substrate for thermal transfer; and
a transfer layer that is provided on the support substrate and includes a host material and a luminescent dopant material each having a sublimation temperature, a difference of the sublimation temperatures being set within a predetermined range.

2. The transfer substrate according to claim 1,
wherein the transfer layer includes a plurality of components of the host material and the luminescent dopant material for forming an organic light emitting layer that emits green light, and
wherein the sublimation temperature of the host material at an atmospheric pressure (T sub-H(° C.)) and the sublimation temperature of the dopant material at the atmospheric pressure (T sub-D(° C.)) satisfy Equation (1) as follows:
−65(° C.)≦(T sub-H)−(T sub-D)≦89(° C.) (1).

3. The transfer substrate according to claim 1,
wherein the transfer layer includes a plurality of components of the host material and the luminescent dopant material for forming an organic light emitting layer that emits green light, and
wherein the sublimation temperature of the host material at an atmospheric pressure (T sub-H(° C.)) and the sublimation temperature of the dopant material at the atmospheric pressure (T sub-D(° C.)) satisfy Equation (2) as follows:
−33(° C.)≦(T sub-H)−(T sub-D)≦56(° C.) (2).

4. The transfer substrate according to claim 1,
wherein the transfer layer includes a plurality of components of the host material and the luminescent dopant material for forming an organic light emitting layer that emits green light, and
wherein the sublimation temperature of the host material at an atmospheric pressure (T sub-H(° C.)) and the sublimation temperature of the dopant material at the atmospheric pressure (T sub-D(° C.)) satisfy Equation (3) as follows:
−28(° C.)≦(T sub-H)−(T sub-D)≦56(° C.) (3).

5. The transfer substrate according to claim 1,
wherein the transfer layer includes a plurality of components of the host material and the luminescent dopant material for forming an organic light emitting layer that emits red light, and
wherein the sublimation temperature of the host material at an atmospheric pressure (T sub-H(° C.)) and the sublimation temperature of the dopant material at the atmospheric pressure (T sub-D(° C.)) satisfy Equation (4) as follows:
−111(° C.)≦(T sub-H)−(T sub-D)≦78(° C.) (4).

6. The transfer substrate according to claim 1,
wherein the transfer layer includes a plurality of components of the host material and the luminescent dopant material for forming an organic light emitting layer that emits red light, and
wherein the sublimation temperature of the host material at an atmospheric pressure (T sub-H(° C.)) and the sublimation temperature of the dopant material at the atmospheric pressure (T sub-D(° C.)) satisfy Equation (5) as follows:
95(° C.)≦(T sub-H)−(T sub-D)≦51(° C.) (5).

7. The transfer substrate according to claim 1,
wherein the transfer layer includes a plurality of components of the host material and the luminescent dopant material for forming an organic light emitting layer that emits red light, and
wherein the sublimation temperature of the host material at an atmospheric pressure (T sub-H(° C.)) and the sublimation temperature of the dopant material at the atmospheric pressure (T sub-D(° C.)) satisfy Equation (6) as follows:
−95(° C.)≦(T sub-H)−(T sub-D)≦25(° C.) (6).

8. The transfer substrate according to any one of claims 1 to 7,
wherein the support substrate includes a photothermal conversion layer.

9. A method of manufacturing a display apparatus, comprising:
preparing a transfer substrate including a support substrate for thermal transfer and a transfer layer that is provided on the support substrate and includes a host material and a luminescent dopant material each having a sublimation temperature, a difference of the sublimation temperatures being set within a predetermined range;
arranging the transfer substrate to be opposed to an apparatus substrate with the transfer layer facing the apparatus substrate; and
sublimating the host material and the dopant material uniformly by heating the transfer layer, and forming a light emitting layer by thermally transferring the transfer layer including the host material and the dopant material to the apparatus substrate.

10. The method of manufacturing a display apparatus according to claim 9,
wherein the support substrate includes a photothermal conversion layer, and
wherein the photothermal conversion layer is irradiated with a laser beam when the thermal transfer is performed.
